(19) United States
(12) Patent Application Publication
(10) Pub. No.: US 2023/0275447 A1
(43) Pub. Date: Aug. 31, 2023

(54) BATTERY TESTING IN OPERATION

(71) Applicant: VESTAS WIND SYSTEMS A/S, Aarhus N. (DK)

(72) Inventors: Chunyang ZHAO, Aarhus N (DK); Lars Christian CHRISTENSEN, Viborg (DK)

(21) Appl. No.: 18/014,313

(22) PCT Filed: Jun. 28, 2021
(86) PCT No.: PCT/DK2021/050211

§ 371 Date: Jan. 3, 2023

(30) Foreign Application Priority Data
Jul. 1, 2020 (DK) PA 2020 70446

(51) Int. Cl. H02J 7/00; H02J 3/38; H01M 10/44

(52) U.S. Cl. CPC H02J 7/00712; H02J 7/0013; H02J 3/38; H02J 7/0047; H01M 10/441

(57) ABSTRACT

According to embodiments described herein managing power storage and discharge from or charge to a battery array that includes a plurality of individual batteries, is provided by: determining an aggregate demand for power from the battery array; performing one of discharging or charging via a first battery of the plurality of individual batteries from a first state of charge to a second state of charge based on a test profile configured to characterize the first battery, wherein the test profile is unrelated to the aggregate demand; and performing the one of discharging or charging via a second battery of the plurality of individual batteries to compensate for a difference between power discharged or charged by the first battery according to the test profile and the aggregate demand.

### BACKGROUND

### Field of the Invention

Embodiments presented in this disclosure generally relate to battery arrays. Particularly, this disclosure provides control schemes to identify the operational characteristics of individual batteries or cells in an array without taking the battery or cells undergoing characterization offline for testing.

### Description of the Related Art

Batteries are an important component in providing reliable power such as in power backup scenarios which can be used independently to “ride through” a loss of power from an electrical grid, to bridge power needs when switching power sources (e.g., between a public power grid to a private generator), or to store and/or smooth power generation from wind, solar, or other intermittent power sources.

When deploying batteries for use as power storage devices, it is important that the operational characteristics of the battery be determined. The improper use of a battery outside of its operational characteristics can degrade the operational lifetime of the battery, reduce the efficiency of the battery in responding to discharge commands, and increase the time and power needed to charge the battery. Batteries can be provided with baseline operational characteristics (e.g., from a manufacturer), but as time progresses and the battery is cycled through charge/discharge cycles in an environment with variable temperature, humidity, and power supply/demand characteristics, etc., the battery can deviate from the baseline operation characteristics. Battery cell tests are necessary to characterize the operational characteristics of in-the-field (or refurbished) batteries to track the actual operational characteristics to best use these batteries (per operator preferences) and keep them in the best operational health for as long as possible. Battery cell tests, however, are expensive, time consuming, and can place or keep a cell out of operation while determining the operational characteristics of that cell.

### SUMMARY

One embodiment of the present disclosure is a method for managing power storage and discharge from or charge to a battery array that includes a plurality of individual batteries, the method comprising: determining an aggregate demand for power from the battery array; performing one of discharging or charging via a first battery of the plurality of individual batteries from a first state of charge to a second state of charge based on a test profile configured to characterize the first battery, wherein the test profile is unrelated to the aggregate demand; and performing the one of discharging or charging via a second battery of the plurality of individual batteries to compensate for a difference between power discharged or charged by the first battery according to the test profile and the aggregate demand.

In another aspect with any method discussed above or below, the second battery is operated to cycle between a third state of charge and a fourth state of charge according to an operational profile for the second battery.

In another aspect with any method discussed above or below, the method further comprises: charging a third battery of the plurality of individual batteries when the aggregate demand is exceeded by the power discharged from the first and second batteries.

In another aspect with any method discussed above or below, the method further comprises: charging a fourth battery of the plurality of individual batteries from a third state to a fourth state according to a second test profile for the fourth battery while the first and second batteries discharge, wherein an amount of power to charge the fourth battery to the fourth state from the third state is included in the aggregate demand.

In another aspect with any method discussed above or below, the method further comprises: updating an operational profile for the first battery after cycling the first battery from the second state back to the first state, wherein the operational profile identifies states of charge that the first battery is to operate between.

In another aspect with any method discussed above or below, the method further comprises wherein the one of discharging or charging is discharging and before discharging the first battery based on the test profile; ensuring that the aggregate demand has a total power demand equal to or greater than the power discharged by the first battery from the first state of charge to the second state of charge.

One embodiment of the present disclosure is a system for manacling power storage and discharge from or charge to a battery array that includes a plurality of individual batteries, the system comprising: a processor; and a memory including instructions embodied therewith that when executed by the processor perform an operation comprising: determining an aggregate demand for power from the battery array; performing one of discharging or charging via a first battery of the plurality of individual batteries from a first state of charge to a second state of charge based on a test profile configured to characterize the first battery, wherein the test profile is unrelated to the aggregate demand; and performing the one of discharging or charging via a second battery of the plurality of individual batteries based on a difference between power discharged or charged by the first battery according to the test profile and the aggregate demand.

In another aspect with any system discussed above or below, the second battery is operated to cycle between a third state of charge and a fourth state of charge according to an operational profile for the second battery.

In another aspect with any system discussed above or below, the operation further comprises: charging a third battery of the plurality of individual batteries when the aggregate demand is exceeded by the power discharged from the first and second batteries.

In another aspect with any system discussed above or below, the operation further comprises: charging a fourth battery of the plurality of individual batteries from a third state to a fourth state according to a second test profile for the fourth battery while the first and second batteries discharge, wherein an amount of power to charge the fourth battery to the fourth state from the third state is included in the aggregate demand.

In another aspect with any system discussed above or below, the operation further comprises: updating an operational profile for the first battery after cycling the first battery from the second state back to the first state, wherein the operational profile identifies states of charge that the first battery is to operate between.

In another aspect with any system discussed above or below, the operation further comprises: when the one of discharging or charging is discharging and before discharging the first battery based on the test profile, ensuring that the aggregate demand has a total power demand equal to or greater than the power discharged by the first battery from the first state of charge to the second state of charge.

One embodiment of the present disclosure is a method for managing power storage and discharge from or charge to a battery array that includes a plurality of individual batteries, the method comprising: segmenting the battery array into: a first battery group selected for characterization according to a test profile; a second battery group selected as a backup charging source; a third battery group selected as a backup discharging source; and a fourth battery group; isolating the first battery group, the second battery group, and the third battery group from a load served by the battery array while leaving the fourth battery group connected to supply stored power to the load; performing a first one of discharging or charging via the second battery group from a first state of charge to a second state of charge via a second one of discharging or charging the first battery group from a third state of charge to a fourth state of charge according to the test profile; and in response to the first battery group discharging or charging less power when discharging or charging from the third state of charge to the fourth state of charge than the second battery group draws when charging or supplies when discharging from the first state of charge to the second state of charge, supplementing the first battery group via the second one of discharging or charging the third battery group from a fifth state of charge to a sixth state of charge

In another aspect with any method discussed above or below, the second battery group is discharged or charged from the first state of charge to the second state of charge according to a second test profile.

In another aspect with any method discussed above or below, the third battery group is selected based on an operational profile of the batteries comprising the third battery group and a difference between a power demand for discharging or charging the second battery group and a power output or power demand from the first battery group.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an operational layout for an array of batteries connected to a load, according to embodiments of the present disclosure.

FIGS. 2A-2C illustrate different characterization profiles for different batteries, according to embodiments of the present disclosure.

FIG. 3 illustrates a characterization profile for a battery, according to embodiments of the present disclosure.

FIG. 4 is a flowchart of a method for deploying and developing profiles for a battery in a battery array, according to embodiments of the present disclosure.

FIG. 5 illustrates a layout for battery characterization as may be used in an off-grid or self-contained grid, according to embodiments of the present disclosure,

FIG. 6 illustrates a demand curve from a load as met by two or more batteries in a battery array, according to embodiments of the present disclosure.

FIG. 7 is a flowchart for a method for testing a battery during operations of the battery array, according to embodiments of the present disclosure.

FIG. 8 is a flowchart of a method for managing power storage and discharge from a battery array that includes a plurality of individual batteries, according to embodiments of the present disclosure.

FIG. 9 is a flowchart for a method for managing power storage and discharge from or charge to a battery array that includes a plurality of individual batteries, according to embodiments of the present disclosure.

FIG. 10 is a block diagram of a controller unit, according to one or more embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

The present disclosure provides for testing and characterization of batteries that are in operation, so that the one or more batteries selected for cell testing respond to an actual power demand on the battery array. The batteries selected for testing output stored power according to a test profile that causes the selected batteries to discharge/charge from a first state of charge (also referred to as a SoC) to a second state of charge during a specified time period. In various embodiments, batteries not selected for testing are activated to charge or discharge according to the respective use profiles to compensate for any differences between the actual demand and the test output/demand. Additionally or alternatively, any power generation sources used in conjunction with the battery array can be controlled to increase/decrease power output based on the power output from or drawn by the batteries during cell test.

As used herein, “draw” refers to power supplied from a source to a consuming system, whereas “demand” refers to power needed by a consuming system. Accordingly, a consuming system may draw power to meet a demand, and that power can be drawn from several different sources including one or more batteries undergoing test operations.

### EXAMPLE EMBODIMENTS

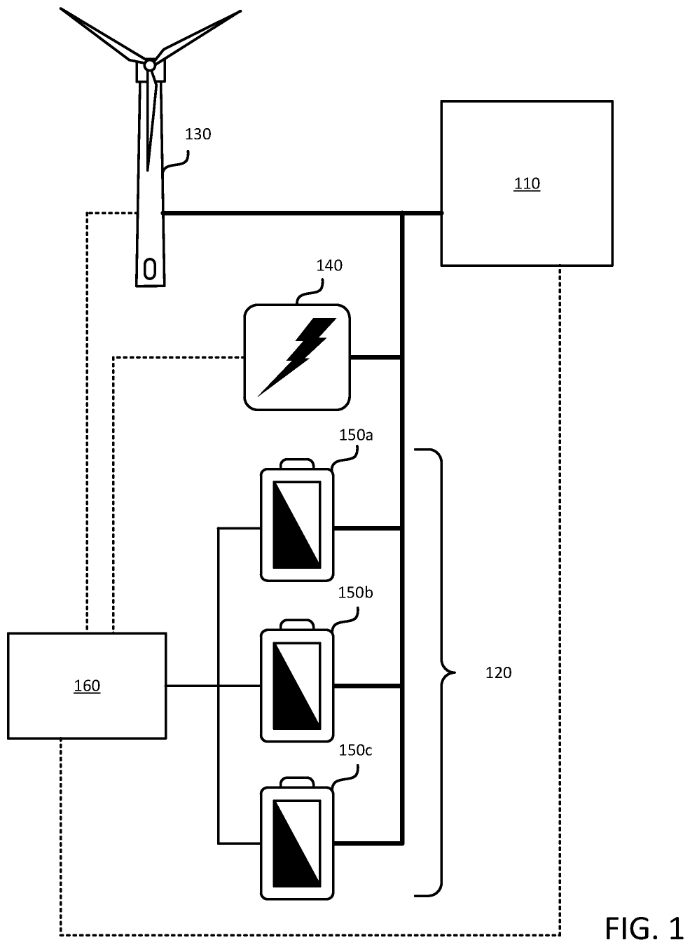

FIG. 1 illustrates an operational layout for an array 120 of batteries 150 connected to a load 110, according to embodiments of the present disclosure. In various embodiments, the load 110 may be a public utility grid, a private sub-grid (e.g., a building or campus, whether normally connected to a public utility grid or not), or a sub-set of the a private sub-grid (e.g., circuits for computers in a server room of a building, but not other circuits.) The load 110 draws power from one or more power sources including renewable power sources 130 (e.g., wind turbine generators, photovoltaic generators, hydroelectric generators), fueled power sources 140 (e.g., generators using diesel, propane, natural gas, hydrogen, biomass, etc.), and a battery array 120. In various embodiments, the load 110 may draw power from one or more of the renewable power sources 130, fueled power sources 140, and the battery array 120 in addition to or to replace of a connection to an external power grid (not illustrated).

The battery array 120 includes a plurality of energy storage systems, which may be charged from power supplied from an external electric grid, one or more of the renewable power sources 130 or fueled power sources 140, or a different member of the battery array 120. For example, a battery array 120 can include a first battery 150a (generally or collectively, battery 150), a second battery 150b, a third battery 150c, etc. Although the batteries 150 used in the battery array 120 are often chemical batteries, the battery array 120 can include various capacitors or mechanical batteries (e.g., flywheels) in addition to the chemical batteries 150.

Each battery 150 of the battery array 120 may have a different construction or chemistry, have a different specified power rating, or be at a different position in a life cycle than other batteries 150 in the battery array 120. For example, a first battery 150a may be a newly installed lead-acid battery with A Ah (Amp hours) of rated capacity, the second battery 150b may be a lead-acid battery with B Ah of rated capacity that has been installed (and in use) for several months, and the third battery 150c may be a Nickel Cadmium (NiCd) battery with C Ah of rated capacity that has been installed (and in used) for several months. As will be appreciated, the battery array 120 can include various numbers of batteries 150 that are different from one another, and can be individually charged, discharged, or replaced/serviced, and the number of batteries 150 can increase or decrease as needed to serve the load 110 and/or replace/service existing batteries 150 in the battery array 120.

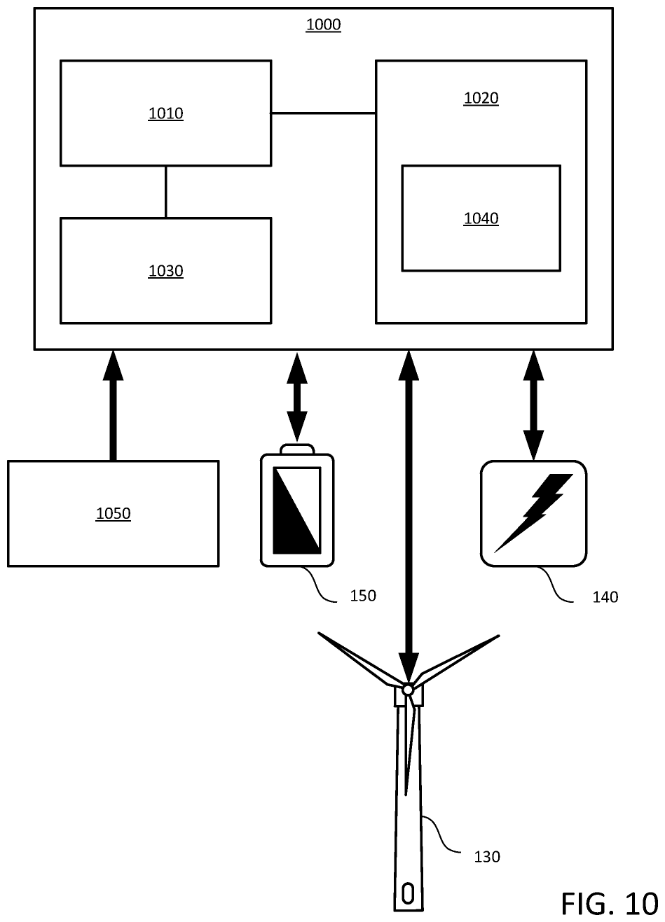

A battery controller 160 is provided to test or characterize the batteries 150 in the battery array 120 and to control when individual batteries 150 charge or discharge. The battery controller 160, which may be a computing device such as that described in greater detail in FIG. 10, is in communication with each battery 150 of the battery array 120 to characterize and control the charging and discharging of the individual batteries 150. In various embodiments, the battery controller 160 is also in communication with the load 110 (or one or more power-draw sensors associated with the load 110), the renewable power sources 130, and the fueled power sources 140 to determine the power output capacity of the generators, a current power output level from the generators, and/or the amount of power being drawn by the load 110. Additionally, the battery controller 160 can be in communication with the generators (e.g., via a power plant controller computing device) to adjust a level of power output of the generators in conjunction with the batteries 150.

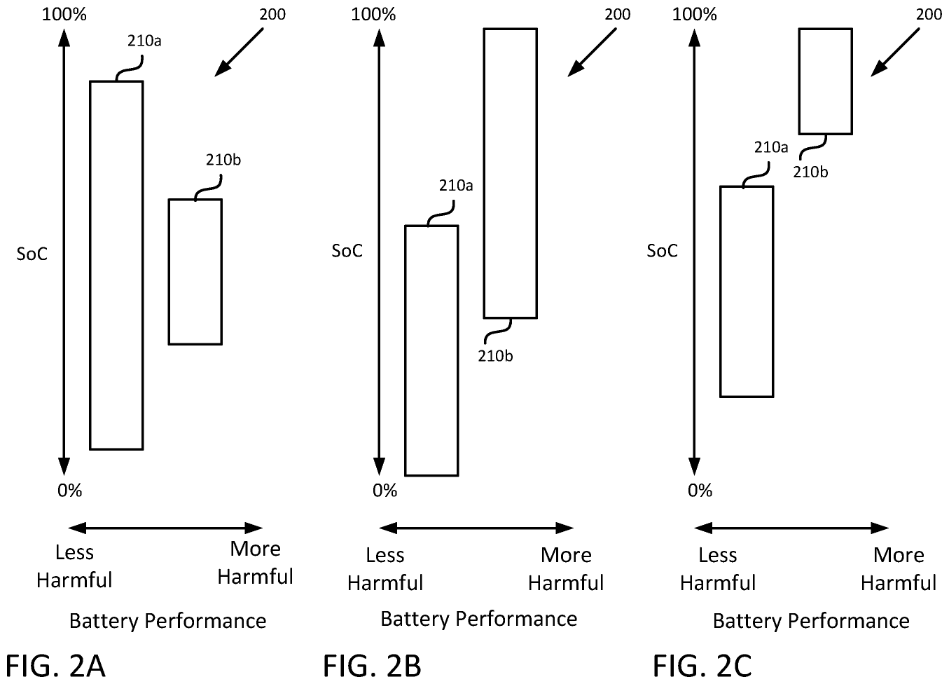

FIGS. 2A-2C illustrate different characterization profiles for different batteries 150a-c, according to embodiments of the present disclosure. Depending on how a given battery 150 is cycled from a first SoC to a second SoC (and back to the first SoC), the capabilities of that battery 150 are affected. Cycling a battery 150 can change the overall storage capacity, response time (how quickly a battery 150 can discharge or charge), efficiency of storage, etc. Different batteries 150, based on the construction or previous use of those batteries 150 can exhibit different characterizations 210 with different effects on the capabilities of those batteries 150. In each of FIGS. 2A-2C, a characterization 200a-c of a given battery 150 is shown with a first charge profile 210a that is less harmful to the capabilities of the battery 150 than a second charge profile 210b that is more harmful to the capabilities of the battery 150.

In FIG. 2A, the first characterization 200a shows a contained arrangement, where the SoC range of a more harmful second charge profile 210b is contained within with the SoC range of the less harmful first charge profile 210a. For example, the first charge profile 210a indicates a cycle from 60% to 20% SoC and the second charge profile 210b indicates a cycle from 40% to 30% SoC.

In FIG. 2B, the second characterization 200b shows an intersected arrangement, where the SoC range of a more harmful second charge profile 210b intersects with the SoC range of the less harmful first charge profile 210a. For example, the first charge profile 210a indicates a cycle from 60% to 0% SoC and the second charge profile 210b indicates a cycle from 100% to 40% SoC; having an intersection between 40% and 60% SoC. In another example, the first charge profile 210a may indicate a cycle from 100% to 40% SoC and the second charge profile 210b may indicate a cycle from 60% to 0% SoC; also having an intersection between 40% and 60% SoC, but reversed positions of the more/less harmful profiles compared to the first example.

In FIG. 2C, the third characterization 200c shows a separated arrangement, where the SoC range of a more harmful second charge profile 210b does not intersect with the SoC range of the less harmful first charge profile 210a. For example, the first charge profile 210a indicates a cycle from 75% to 30% SoC and the second charge profile 210b indicates a cycle from 100% to 90% SoC; having a separation between 75% and 90% SoC. In another example, the first charge profile 210a may indicate a cycle from 100% to 90% SoC and the second charge profile 210b may indicate a cycle from 75% to 30% SoC; also having a separation between 75% and 90% SoC, but reversed positions of the more/less harmful profiles compared to the first example.

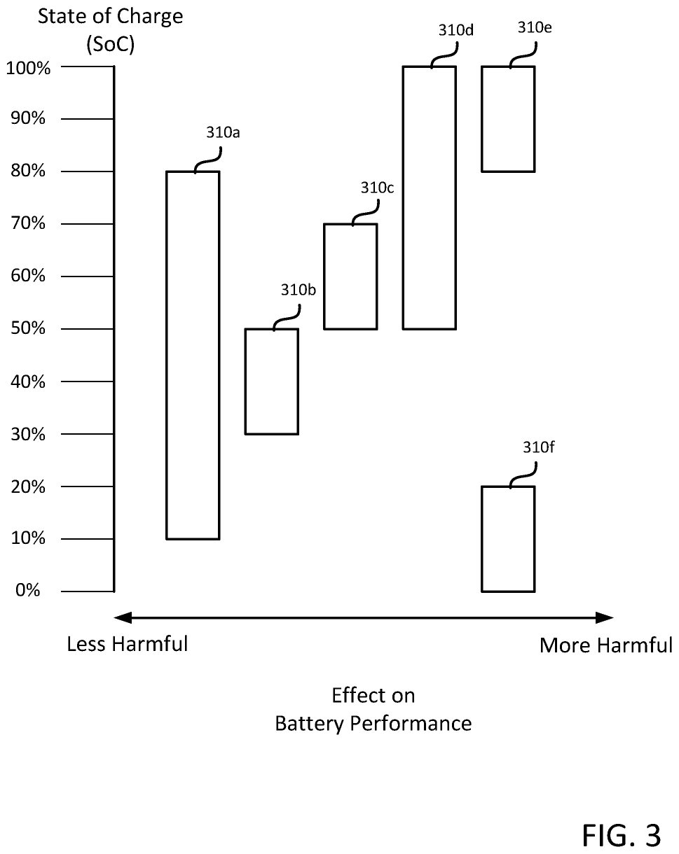

FIG. 3 illustrates a characterization profile for a battery 150, according to embodiments of the present disclosure. The battery controller 160 can receive, develop, and update a plurality of charge profiles 310a-f for a given battery 150 or cohort of similar batteries 150 in the battery array 120 (e.g., those batteries 150 having the same construction and installation/use history) to develop a better understanding of how the batteries can best be used to preserve the operational capabilities of those batteries. The battery controller 160 ranks the charge profiles 310a-f based on user supplied metrics for whether to prioritize preserving overall capacity, response time, efficiency of storage, etc. As will be appreciated, the battery controller 160 may maintain and rank more or fewer than six charge profiles 310a-f in other embodiments.

The battery controller 160 activates various batteries 150 to cycle between two states of charge (charging and/or discharging) according to an operational profile. As described herein, an operational profile identifies a known behavior pattern to cycle between two states of charge to preserve the overall health of the battery array 120, where a user defines which capabilities of the batteries 150 to prioritize preserving. Stated differently, the operational profile is the highest rated or “least harmful” charge profile for a given battery 150 that is known to the battery controller 160. For example, in FIG. 3, the first charge profile 310a can be selected as the operational profile so that the batteries 150 cycle from 80% to 10% SoC when possible. When not possible to cycle according to the first charge profile 310a, the operational profile prioritizes cycling the battery 150 according to the second charge profile 310b, the third charge profile 310c, etc., so as to maximize the overall health of the array 120 while meeting the operational demands of the load 110.

In contrast, a test profile describes a charge profile that has an unknown effect on the battery 150 operating according to the test profile. Stated differently, a test profile, before being run, can have any ranking among the known charge profiles. For example, before the battery controller 160 observes a battery 150 cycle according to first charge profile 310a, the first charge profile 310a is a test profile. The battery controller 160 would therefore use an operational profile that prioritizes the second charge profile 310b as the highest rated charge profile until the first charge profile 310a is observed.

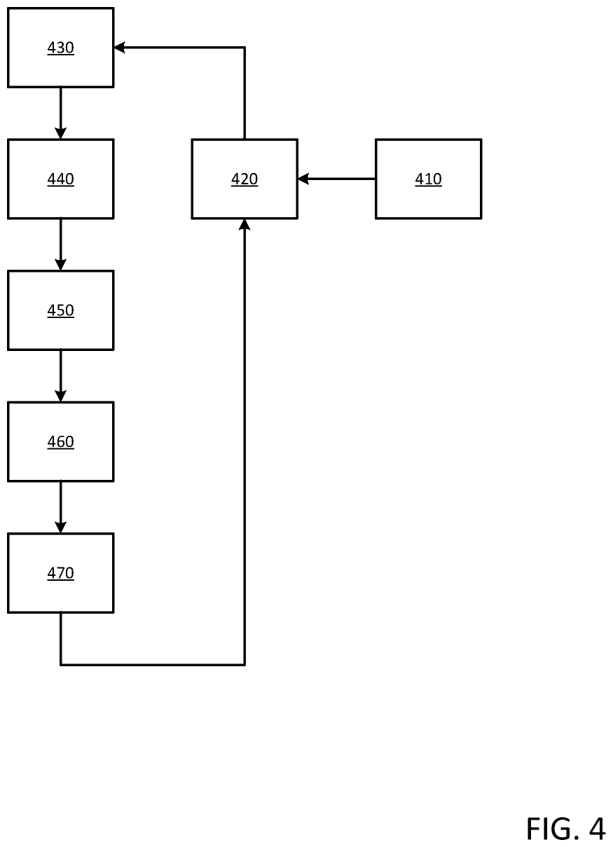

FIG. 4 is a flowchart of a method 400 for deploying and developing profiles for a battery 150 in a battery array 120, according to embodiments of the present disclosure. Method 400 begins at block 410, where an initial profile is loaded. In various embodiments, an initial profile can be based on a manufacturer's initial life testing of the model that the battery 150 conforms to, but may also be based on models gathered or developed by an operator based on previous observations of similarly batteries 150. For example, when installing a newly manufactured battery 150, the battery controller 160 may load a profile provided from a manufacturer as the initial profile, whereas when installing a refurbished battery 150, the battery controller 160 may load an initial profile based on one or more of the manufacturer's profile or a profile of a similarly refurbished battery.

At block 420, the battery controller 160 sets operational guidance based on the operational profiles known for the plurality of individual batteries 150 that make up the battery array 120. The operational guidance can be set according to various user-defined parameters to increase overall operational lifetime of the battery array 120, to prioritize the operational lifetime of designated batteries 150 in the battery array 120 (e.g. over the operational lifetimes of other batteries 150), response speed in some or all of the batteries 150 (to react to changes in demand on the battery array 120), and other characteristics of individual batteries 150 or the array 120 as a whole including, but not limited to: power usage, energy usage, frequency of usage, recovery effect, long time storage, and temperature/humidity operational conditions. The demand can include a current demand for power and/or a predicted demand for power in the future including the duration of the predicted demand, a magnitude of the predicted demand, and a steadiness/variability of the predicted demand.

At block 430, the battery controller 160 identifies the demand from the load 110 that will draw power from one or more batteries 150 in the array 120. In various embodiments, the demand can include various draws to charge one or more batteries 150 in the array 120, including those undergoing characterization and those charging as part of normal operations of the array 120. In various embodiments, an energy management system or power plant controller dispatches the portion of the demand that the battery array 120 is to handle to the battery controller 160 with a remainder being handled by one or more renewable power sources 130 or fueled power sources 140.

At block 440, the battery controller 160 dispatches the portion of the demand to be handled by different groups of batteries 150 in the array 120. For example, a first group of batteries 150 in the array may have an operational profile that is prioritized for initial response to demand (e.g., due to a quick reactiveness of the batteries 150, a low impact of fast reaction on the batteries 150, a low impact of sustained power discharge, etc.), and a second group of batteries 150 may have an operational profile that is not prioritized for initial response, and instead is held in reserve until the total demand exceeds what the first group of batteries 150 can supply. Accordingly, the battery controller 160 can operate several battery groups in the array 120 according to different operational profiles to meet the total power demand on the battery array 120 while preserving the capabilities of the batteries 150 therein based on the developed operational profiles.

At block 450, based on the operation of the batteries 150, the batteries 150 degrade. The capabilities of the batteries 150 degrade over time and with use, and as different groups of batteries 150 are used differently, various differences in the operational capabilities of the batteries 150 develop, even in batteries 150 of the same construction that have been installed for the same amount of time in the same environment. Stated differently, the different operational profiles used to select which batteries 150 are cycled to meet demand for stored power can cause the batteries 150 (even if identical before the cycling) to diverge in capabilities over time.

At block 460, the battery controller 160 collects battery performance data, including cross-system data, that indicate how the batteries 150 are performing and the capabilities of those batteries 150. These data can include power input to charge the batteries 150, voltage levels of the batteries 150 (or at nodes supplied by the batteries 150), environmental conditions (e.g., temperature, humidity, atmospheric pressure, etc.) and the like that affect the performance of the batteries 150.

At block 470, the battery controller 160 identifies one or more batteries 150 to undergo characterization and develop a test profile to updated or expand the operation profile for those batteries 150. The test profiles are provided to put one or more cells of the identified batteries 150 into an operational mode of interest the next time a demand is place on the battery array 120. For example, the battery controller 160 temporarily replace an operational profile for a battery 150 with a test profile (per block 420) to cycle the battery 150 between two states of charge that have not previously been observed for the battery 150. Method 400 may then return to block 420 to update the operational profiles based on the observed battery performance data (collected per block 460) and/or the identified test profiles.

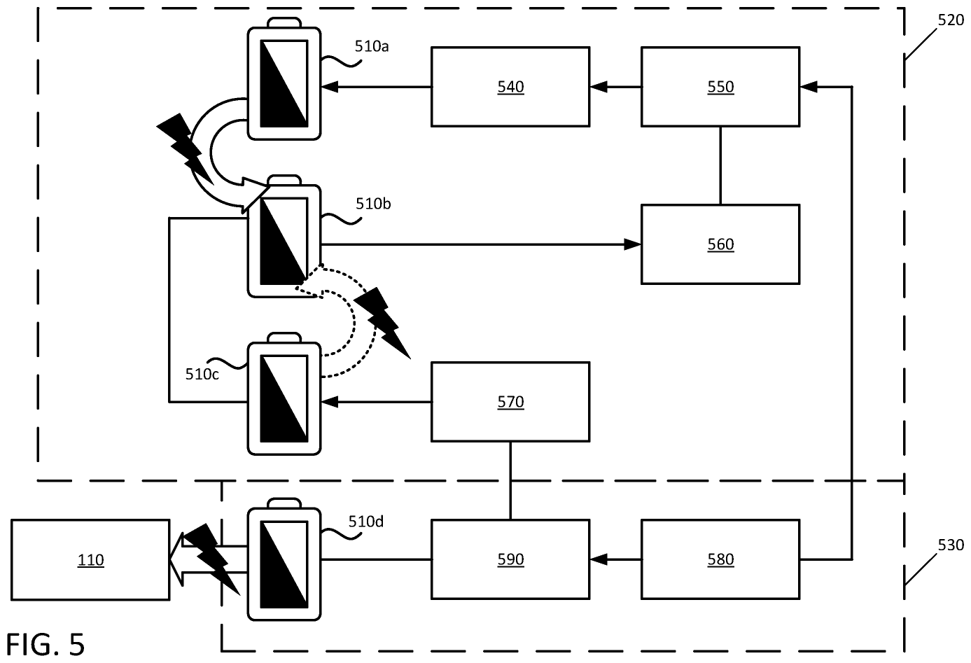

FIG. 5 illustrates a layout for battery characterization as may be used in an off-grid or self-contained grid, according to embodiments of the present disclosure. A first battery group 510a is selected to undergo characterization, while a second battery group 510b and a third battery group 510c are respectively selected as a backup charging source and a backup discharging source. The first through third battery groups 510a-c remain installed and ready for operational use, but are set aside for testing and are not used for responding to operational demands for stored power from the load 110, instead, a fourth battery group 510d is selected to remain as an operating group to meet the needs of the load 110 while the first battery group 510a undergoes test.

The battery controller 160 selects which batteries 150 belong to a given battery group 510a-d based on the electrical loads and requirements/resources available to the battery array 120. The battery controller 160 can reassign individual batteries 150 to different groups across different tests and matches the charging and discharging requirements for first battery group 510a with the second through fourth battery groups 510b-d to keep at least a portion of the battery array 120 available to respond to demand for stored power. Accordingly, the battery array 120 as a whole need not be shut down or taken offline for testing, but is provided with partial capacity reserved for operational needs and partial capacity devoted to testing. Stated differently, the batteries 150 and design considerations can be divided into a testing setup 520 and an operational setup 530, and the battery controller 160 can keep the battery array 120 available for operational use while a test is underway.

In various embodiments, each of the battery groups 510a-d may include the same or a different number of batteries 150 from one another. When selecting which batteries 150 are assigned to the first through fourth battery groups 510a-d, the battery controller 160 balances the various needs for power discharge and storage for the test and the operation of the load 110 served by the battery array 120. For example, the battery controller 160 considers the testing load design 540 (e.g., how the first battery group 510a is to be cycled), the primary power sources 550 (e.g., local generators, an electrical grid) and secondary power sources 560 (e.g., the charge available from the second battery group 510b) available for charging the first battery group 510a, and the auxiliary load 570 to be served by third battery group 510c in the testing setup 520. Additionally. The battery controller 160 considers the operational load requirement 590 and use case requirements 580 for whether the fourth battery group 510d can continue to serve the load 110, and whether a portion of the operational load requirement 590 can be shifted to the auxiliary load 570 for at least a portion of the test.

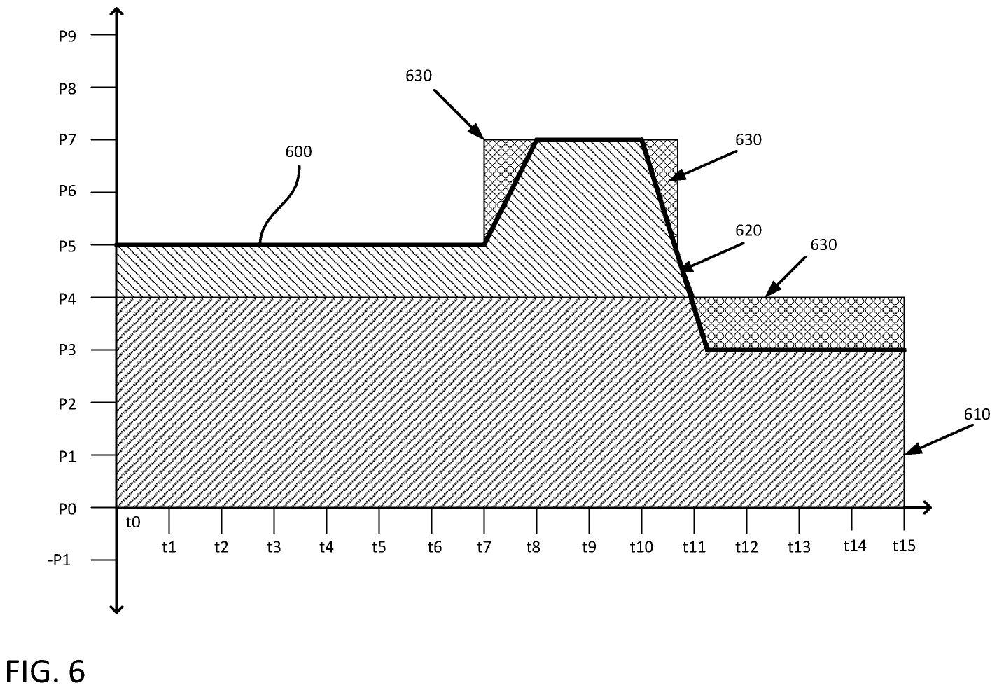

FIG. 6 illustrates a demand curve 600 from a load 110 and/or charging battery 150 as met by two or more batteries 150 in a battery array 120, according to embodiments of the present disclosure. The demand curve 600 is shown over a period of time from t₀ to t₁₅ with a demand ranging from P₃ to peak demand at P₇. To meet the needs of the load 110, as indicated by the power demand curve 600, the power plant controller may discharge one or more batteries 150 from the battery array 120. The battery controller 160 identifies which batteries 150 from the battery array 120 to discharge based on the current and predicted demand for power from the load 110 and one or more operational or test profiles for those batteries 150.

In FIG. 6, the battery 150 undergoing test is discharging at a power level of P₄ from time t₀ to t₁₅ for a first output 610, despite the demand curve 600 indicating that the bad 110 drawing more than or less than P₄ for most of the time range. When selecting a battery 150 to discharge according to a test profile, the battery controller 160 discharges that battery 150 without regard to the demand from the bad 110. Stated differently, when a first battery 150a undergoing test discharges less power than is needed to meet the demand curve 600, a second battery 150b is selected and discharged according to an operational profile to meet the power need indicated by the demand curve 600. Similarly, when a first battery 150a discharges more power than is needed to meet the demand curve 600, any excess discharge can be absorbed by charging a third battery 150c according to a corresponding operational (or test) profile. Accordingly, the characterization test of the first battery 150a can be run uninterrupted by the battery controller 160, and the best-fit batteries from the batteries 150 not undergoing test can be selected to compensate for the output to demand difference.

In FIG. 6, a second output 620 is provided by one or more other batteries 150 to supply any difference between the first output 610 and the demand curve 600. The battery controller 160 selects the individual batteries 150 to provide the second output 620 based on the operational profiles and current states of charge for those batteries 150 to promote the longevity of the battery array 120 as a whole. In various embodiments, the particular batteries 150 discharged to supply the second output 620 are used for some or all of the range of time that additional discharge is required. For example, with reference to second output 620 in FIG. 6 in the time range from t₀ to t₁₁, a first battery 150a can output P from time t₀ to time t₄, a second battery can output P₁ time t₄ to time t₁₁, and a third battery 150c can output P₂ from time t₇ to t₁₁. In various embodiments, the battery controller 160 can designate one or more batteries 150 that provide the second output 620 to discharge a variable amount of power so that there is no (or minimal) over-discharge, but the battery controller 160 can also designate one or more batteries 150 to charge via any excess power discharged.

When the power demand curve 600 is less than the first output 610 from the battery 150 undergoing characterization, such as from t₁₁ to t₁₅, or when the second output 620 is greater than the power demand curve 600 (from the combined battery 150 under test and discharging batteries 150 not under test), such as from t₇ to t₁₁, the battery controller 160 can select on or more batteries 150 to charge using the excess power 630. The battery controller 160 selects the various batteries 150 to charge based on the current SoC of the batteries 150, the operational profiles of the batteries 150, and whether one or more of the batteries 150 are scheduled for charging according to a test profile. As will be appreciated, one or more batteries 150 selected for discharge characterization can be paired with one or more batteries 150 selected for charge characterization to increase the number of batteries 150 that can be characterized in a given period for a given power demand from the load 110.

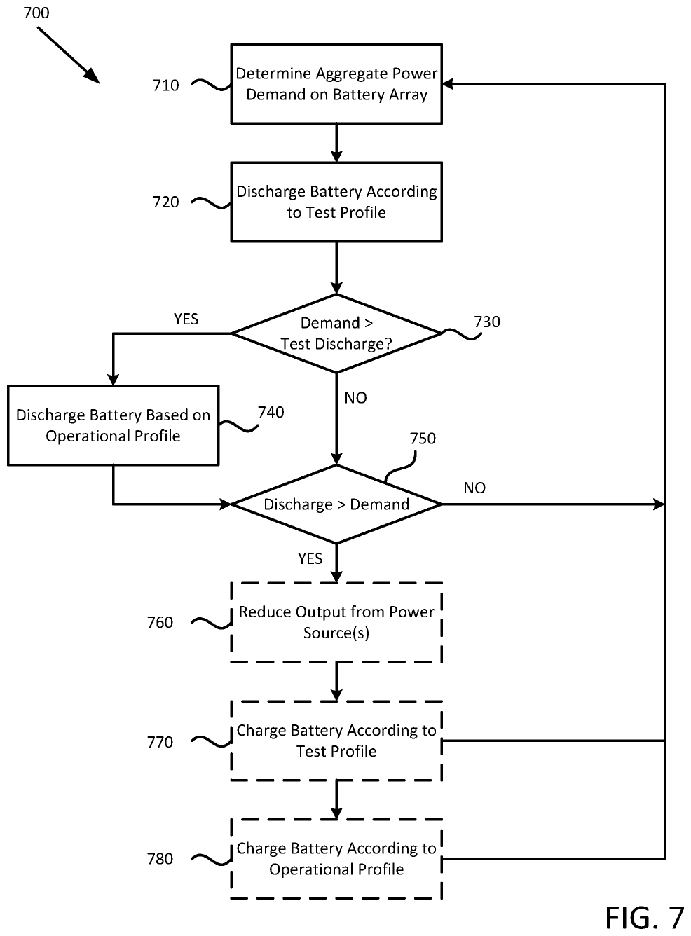

FIG. 7 is a flowchart for a method 700 for testing a battery 150 during operations of the battery array 120, according to embodiments of the present disclosure. Method 700 begins at block 710, where the battery controller 160 determines an aggregate power demand on the battery array 120. In various embodiments, the aggregate power demand includes the demand from the load 110 (less any power supplied by a renewable power source 130 or fueled power source 140 operated in conjunction with the battery array 120) and the demand to charge any batteries 150 in the battery array 120. In various embodiments, the battery controller 160 may identify whether the demand is predicted to last for at least a threshold duration and/or draw a threshold amount of power before determining to discharge a battery 150 according to a test profile, however, the power discharged according to the test profile is unrelated to the power demanded from the load 110. Stated differently, because the power produced by discharging the battery according to the test profile is unrelated to power demand from the load 110, the battery controller 160 compensates for any difference between demand and discharge by activating other batteries 150 in the array 120, but may schedule the characterization test based on the (predicted) demand to reduce the amount of and/or impact on other batteries 150 needed to offset any difference.

At block 720, the battery controller 160 signals one or more batteries 150 to discharge in response to the demand based on a test profile. In various embodiments, the test profile may cause the battery 150 to discharge more or less power than is being drawn by the load 110. Accordingly, the battery controller 160 determines at block 730 whether the demand for power is greater than the test discharge provides. When demand is greater than the power discharged according to the test profile, method 700 proceeds to block 740. When the demand is not greater than the power discharged accord to the test profile, method 700 proceeds to block 750.

At block 740, the battery controller 160 signals one or more batteries to discharge in conjunction with the batteries 150 undergoing characterization. The battery controller 160 selects the supplemental batteries 150 to discharge based on the operational profiles of those batteries 150 to meet (or exceed) the aggregate power demand while maintaining the overall health of the battery array 120 according to user preferences.

At block 750, the battery controller 160 determines whether the power discharged by the batteries 150 undergoing test according to the test profile and/or the supplemental batteries 150 discharging according to the respective operational profiles is greater than the aggregate power demand (i.e., the discharge of the batteries 150 undergoing test plus the discharge of the any batteries 150 operating according to operational profiles equals the power demand). When the power provided by the batteries 150 is not greater than the aggregate demand, method 700 returns to block 710 to continue monitoring the aggregate demand and adjusting which batteries 150 in the battery array 120 are activated until the characterization test of the batteries 150 operating according to the test profile concludes. When the power provided by the batteries 150 is greater than the aggregate demand, method 700 proceeds to one or more of block 760, block 770, and/or block 780 to effectively adjust the aggregate demand.

Each of block 760, block 770, and block 780 are optional, and the battery controller 160 can select one, two, or all three to adjust the aggregate demand handled by the battery array 120 in various embodiments. Additionally or alternatively, the battery controller 160 may control one or more batteries 150 in block 740 to match the aggregate demand, and method 700 may omit blocks 760-780.

At block 760, the battery controller 160 signals a power plant controller and/or one or more generators in a shared installation with the battery array 120 to reduce power output. For example, a wind turbine generator may be signaled to feather the blades of the turbine or move a nacelle out of the wind, a photovoltaic cell may be signaled to angle out of the sun, a diesel generator may be signaled to shut down or reduce a fuel consumption rate, etc. Accordingly, by reducing the power generated by other power sources in the shared installation, the amount of aggregate demand that the battery array 120 handles can be adjusted.

At block 770, the battery controller 160 selects one or more batteries 150 to charge according to a test profile. In various embodiments, the battery controller 160 may identify whether the demand is predicted to be low enough or excess storage and/or generation capacity to be high enough for at least a threshold duration before determining to charge a battery 150 according to a test profile. By charging one or more batteries 150, the battery controller 160 increases the aggregate demand for power and consumes some, all, or more than the excess discharge identified in block 750. Method 700 proceeds from block 770 to block 710, where the battery controller 160 continues monitoring the aggregate demand and adjusting which batteries 150 in the battery array 120 are activated (charging or discharging) until the characterization test of the batteries 150 operating according to the test profile concludes.

At block 780, the battery controller 160 selects one or more batteries 150 to charge according to the operational profiles. By charging one or more batteries 150, the battery controller 160 increases the aggregate demand for power and consumes some, all, or more than the excess discharge identified in block 750, Method 700 proceeds from block 780 to block 710, where the battery controller 160 continues monitoring the aggregate demand and adjusting which batteries 150 in the battery array 120 are activated (charging or discharging) until the characterization test of the batteries 150 operating according to the test profile concludes.

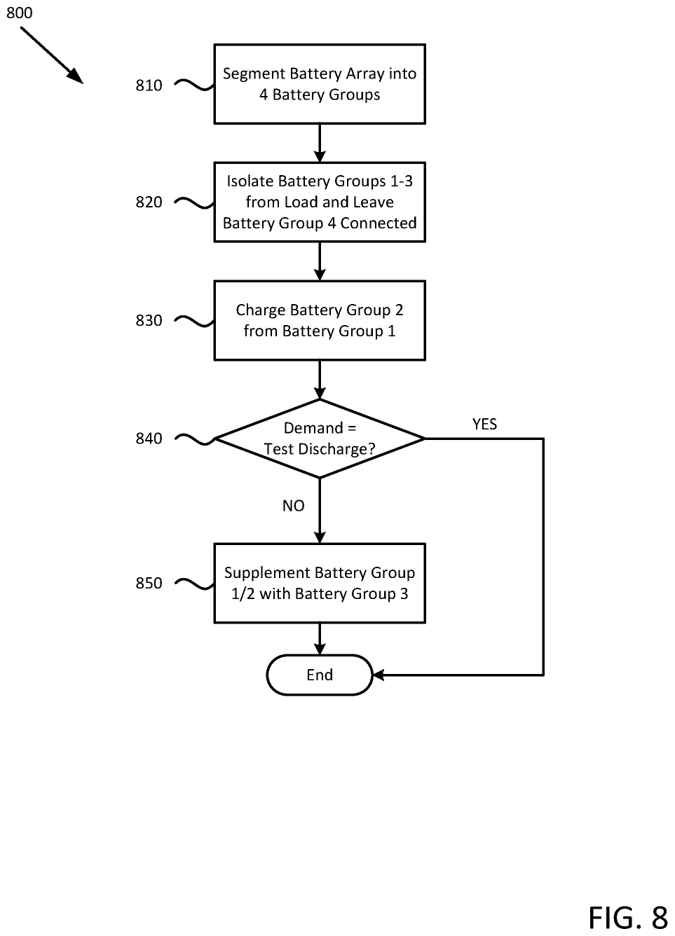

FIG. 8 is a flowchart of a method 800 for managing power storage and discharge from a battery array 120 that includes a plurality of individual batteries 150, according to embodiments of the present disclosure.

Method 800 begins at block 810, where the battery controller 160 segments the battery array 120 into four groups of batteries. The first battery group 510a includes those batteries 150 selected for characterization by cycling between specific states of charge to provide additional information to the battery controller 160 to manage the health of the battery array 120. The second battery group 510b includes those batteries 150 selected to receive the discharged power from the first battery array 120. The third battery group 510c includes those batteries 150 selected to supplement the charging of the second battery group 510b in conjunction with the first battery group 510a. The fourth battery group 510d includes those batteries 150 selected to serve the load 110 while the first through third battery groups 510a-c are engaged in a characterization test.

In various embodiments, the battery controller 160 can select multiple different test profiles to run for different batteries 150 included in the first battery group 510a to have an overall test profile for the first battery group 510a. Additionally, when segmenting the battery array 120, the battery controller 160 can select multiple batteries 150 to comprise the second battery group 510b with different profiles. In various embodiments, some or all of the batteries 150 in the second battery group 510b charge according to test profiles and some or all of the batteries charge according to operational profiles to define an overall profile for the second battery group 510b. Similarly, the battery controller 160 can select the batteries to comprise the third and fourth battery groups 510c-d to have a plurality of different operational profiles.

In various embodiments, the second battery group 510b is charged from a first SoC to a second SoC based on an operational profile, but can also be charged from the first SoC to the second SoC based on a test profile. Charging the second battery group 510b provides a power demand that the first battery group 510a discharges to satisfy. In various embodiments, when the first battery group 510a is matched to the second battery group 510b so that the first battery group 510a discharges from the second SoC to the first SoC at the same rate that the second battery groups charges from the first SoC to the second SoC, the third battery group 510c can include zero batteries. In other embodiments, when the first battery group 510a discharges from a third SoC to a fourth SoC (different from the second and first SoC) and/or at a different rate than the second battery group 510b charges at, the third battery group 510c provides supplemental power discharge to ensure that the second battery group 510d charges according to the specified operational or test profile.

At block 820, the battery controller 160 isolates the first through third battery groups 510a-c from the load 110 served by the battery array. The fourth battery group 510d remains connected to the load 110 to supply stored power to the load 110 in response to demands on the battery array 120. Stated differently, the battery controller 160 prevents the first through third battery groups 510a-c from responding to demand from the bad 110 while leaving the fourth battery group 510d available to respond to demand from the load 110. Accordingly, the battery array 120 remains online and available to provide stored power while performing characterization tests on one or more batteries 150. Because the first through third battery groups 510a-c are isolated from the bad, the amount of power discharged from the first battery group 510a and received by the second battery group 510b is unrelated to any demand from the load 110. Accordingly, the characterization test can be performed when no demand from the bad 110 is placed on the battery array 120 or while the fourth battery group 510d serves the demand from the load 110.

At block 830, the battery controller 160 charges the second battery group 510b from a first state of charge to a second state of charge via discharging the first battery group 510a from a third state of charge to a fourth state of charge according to the test profile(s) for the batteries 150 of the first battery group 510a.

At block 840, the battery controller 160 determines whether the power demanded to charge the second battery group 510b is equal to the power discharged from the first battery group 510a according to the characterization test of the first battery group 510a. In response to determining that the first battery group 510a is discharging less power when discharging from the third state of charge to the fourth state of charge than the second battery group 510b draws when charging from the first state of charge to the second state of charge (either at a different rate or at a different total power level), method 800 proceeds to block 850. Otherwise method 800 may conclude.

At block 850, the battery controller 160 signals the third battery group 510c to supplement the power discharge from the first battery group via discharging the third battery group 510c from a fifth state of charge to a sixth state of charge. In various embodiments, some or all of the batteries 150 comprising the third battery group 510c can discharge at the same time as the batteries 150 comprising the first battery group 510a, or may discharge before or after when the batteries 150 comprising the first battery group 510 discharge. In various embodiments, the third battery group 510c is selected based on an operational profile of the batteries 150 comprising the third battery group 510c and a difference between a power demand for charging the second battery group 510b and a power output from the first battery group 510a to reduce an impact on the health of the second battery group 510b when discharging to supplement the first battery group 510a, Method 800 may then conclude.

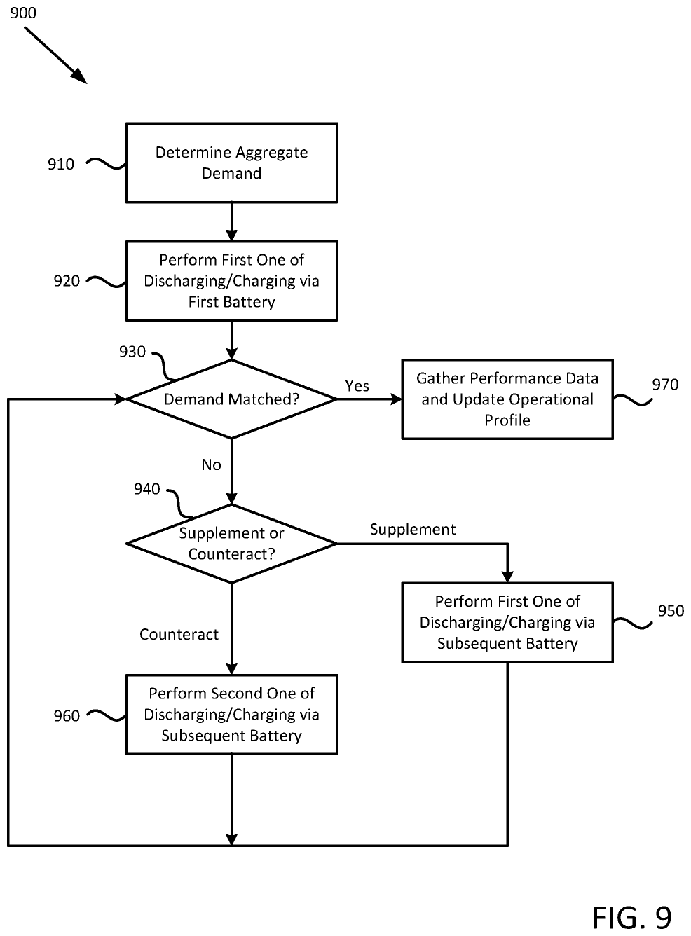

FIG. 9 is a flowchart for a method 900 for managing power storage and discharge from or charge to a battery array 120 that includes a plurality of individual batteries, according to embodiments of the present disclosure.

Method 900 begins at block 910, where the battery controller 160 determines an aggregate power demand on the battery array 120. In various embodiments, the aggregate power demand includes the demand from the load 110 (less any power supplied by a renewable power source 130 or fueled power source 140 operated in conjunction with the battery array 120) and the demand to charge any batteries 150 in the battery array 120. In various embodiments, the battery controller 160 may identify whether the demand is predicted to last for at least a threshold duration and/or draw a threshold amount of power before determining to discharge a battery 150 according to a test profile, however, the power discharged according to the test profile is unrelated to the power demanded from the load 110. Stated differently, because the power produced by discharging the battery according to the test profile is unrelated to power demand from the load 110, the battery controller 160 compensates for any difference between demand and discharge by activating other batteries 150 in the array 120, but may schedule the characterization test based on the (predicted) demand to reduce the amount of and/or impact on other batteries 150 needed to offset any difference.

At block 920, the battery controller 160 signals a first set of one or more batteries 150 (e.g., a first battery 150a) to perform a first one of a discharging or a charging from a first SoC to a second SoC (e.g., discharging from 80% to 20% or charging from 20% to 80%) based on a test profile configured to characterize the one or more batteries 150 undergoing characterization. Because the test profile is unrelated to the aggregate demand, in various embodiments, the test profile may cause the first set performing the first one of discharging/charging to provide more power than is being drawn by the load 110 or draw more power than the generators can provide to the load 110. Accordingly, at block 930, the battery controller 160 determines whether the sets of batteries provide insufficient or excess power by discharging or charging to meet the demand from the load 110. When the batteries provide excess power by discharging too much power, or add too much demand to the aggregate load, by method 900 proceeds to block 940 to identify additional batteries 150 to charge or discharge to match the demand for the load 110. When the batteries provide matched power for the demand from the load 110, method 900 proceeds to block 970 where the battery controller 160 gathers performance data on the batteries 150 undergoing characterization according to test profiles and updates the operational profiles for those batteries 150 (after cycling those batteries from the second SoC back to the first SoC) based on the observed performance data. These performance data can include power input to charge the batteries 150, voltage levels of the batteries 150 (or at nodes supplied by the batteries 150), environmental conditions (e.g., temperature, humidity, atmospheric pressure, etc.) and the like that affect the performance of the batteries 150. The operational profile identifies states of charge that the characterized batteries 150 are to operate between. Method 900 may then conclude.

At block 940, the battery controller 160 determines how to supplement or counteract the discharging/charging of the first set by selecting various other sets of batteries to discharge/or charge to meet the needs of the load 110.

Method 900 proceeds from block 940 to block 950 to supplement operations of the first set of batteries (and any sets of batteries selected per block 960 to counteract the first set of batteries). When supplementing the first set of batteries a second (or other subsequent) set of batteries performs the same one of discharging or charging as the first set of batteries. For example, to compensate for a difference between power discharged by the first set according to the test profile and the aggregate demand (e.g., Δ(power discharged, aggregate demand)), a second set (e.g., a second battery 150b) can discharge additional power to provide additional power to meet the demand from the load 110. In another example, to compensate for a difference between power charged by the first set according to the test profile and the aggregate demand (e.g., Δ(power discharged, aggregate demand)), a second set (e.g., a second battery 150b) can charge additional power to consume excess generation capacity not needed by the load 110. In various embodiments, the second set can be discharged/charge according to an operational profile or a second test profile. Method 900 then proceeds to block 960.

Method 900 proceeds from block 940 to block 960 to counteract operations of the first set of batteries (and any sets of batteries selected per block 950 to supplement the first set of batteries). When counteracting the first set of batteries a third (or other subsequent) set of batteries performs a different one of discharging or charging from the first set of batteries. For example, to compensate for a difference between power discharged by the first set according to the test profile and the aggregate demand (e.g., Δ(power discharged, aggregate demand)), a third set (e.g., a second battery 150c) can charge using the excess power from what the load 110 demands. In another example, to compensate for a difference between power discharged by the first set according to the test profile and the aggregate demand (e.g., Δ(power discharged, aggregate demand)), a fourth set (e.g., a fourth battery 150d) can additional power to provide additional power to meet the demand from the load 110. In various embodiments, the third/fourth set can be discharged/charge according to an operational profile or a third/fourth test profile. Method 900 then proceeds to block 960.

FIG. 10 is a block diagram of a controller unit 1000 as may be used in a battery controller 160 to control several batteries 150 in a battery array 120 and/or one or more generators (via a power plant controller, which may also be a controller unit 1000), according to one or more embodiments. The controller unit 1000 includes one or more computer processors 1010 and a memory 1020. The one or more processors 1010 represent any number of processing elements that each can include any number of processing cores. The memory 1020 can include volatile memory elements (such as random access memory), non-volatile memory elements (such as solid-state, magnetic, optical, or Flash-based storage), and combinations thereof. Moreover, the memory 1020 can be distributed across different mediums (e.g., network storage or external hard drives).

As shown, the one or more processors 1010 are communicatively coupled with a communication system 1030 to send/receive communication via fiber optic cables, electrical wires, and/or radio signals with various sensors 1050 and other controller units 1000 associated with the batteries 150. In some embodiments, the various sensors 1050 are linked to the batteries 150 under the control of the controller unit 1000. In other embodiments, the various sensors 1050 are independent from the batteries 150 under the control of the controller unit 1000. For example, a controller unit 1000 in control of several batteries 150 may send discharge or charge commands to the batteries 150 (or control circuitry associated therewith) and receive sensor data from various voltage/current level, temperature, humidity, etc. sensors that are not associated with a particular battery 150.

The memory 1020 may include a plurality of “modules” for performing various functions described herein. In one embodiment, each module includes program code that is executable by one or more of the processors 1010. However, other embodiments may include modules that are partially or fully implemented in hardware (i.e., circuitry) or firmware. The memory 1020 includes a battery characterization logic 1040 that enables the controller unit 1000 to test the various batteries 150 and build various test profiles and operational profiles for those batteries, which can be stored in the memory 1020 for application in controlling the various batteries 150 and/or performing further tests on the batteries 150.

In the preceding, reference is made to embodiments presented in this disclosure. However, the scope of the present disclosure is not limited to specific described embodiments. Instead, any combination of the features and elements provided above, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages described herein are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

The present invention may be a system, a method, and/or a computer program product. The computer program product may include a computer-readable storage medium (or media) (e.g., a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing) having computer readable program instructions thereon for causing a processor to carry out aspects of the present invention.

Aspects of the present disclosure are described with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the Figures illustrate the architecture, functionality and operation of possible implementations of systems, methods and computer program products according to various embodiments. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In view of the foregoing, the scope of the present disclosure is determined by the claims that follow.

1. A method for managing power storage and discharge from or charge to a battery array that includes a plurality of individual batteries, the method comprising:
determining an aggregate demand for power from the battery array;
performing one of discharging or charging via a first battery of the plurality of individual batteries from a first state of charge to a second state of charge based on a test profile configured to characterize the first battery, wherein the test profile is unrelated to the aggregate demand; and
performing the one of discharging or charging via a second battery of the plurality of individual batteries to compensate for a difference between power discharged or charged by the first battery according to the test profile and the aggregate demand.

2. The method of claim 1, wherein the second battery is operated to cycle between a third state of charge and a fourth state of charge according to an operational profile for the second battery.

3. The method of claim 1, further comprising:
charging a third battery of the plurality of individual batteries when the aggregate demand is exceeded by the power discharged from the first and second batteries.

4. The method of claim 1, further comprising:
charging a fourth battery of the plurality of individual batteries from a third state to a fourth state according to a second test profile for the fourth battery while the first and second batteries discharge, wherein an amount of power to charge the fourth battery to the fourth state from the third state is included in the aggregate demand.

5. The method of claim 1, further comprising:
updating an operational profile for the first battery after cycling the first battery from the second state back to the first state, wherein the operational profile identifies states of charge that the first battery is to operate between.

6. The method of claim 1, further comprising:
wherein the one of discharging or charging is discharging and before discharging the first battery based on the test profile, ensuring that the aggregate demand has a total power demand equal to or greater than the power discharged by the first battery from the first state of charge to the second state of charge.

7. A system for managing power storage and discharge from or charge to a battery array that includes a plurality of individual batteries, the system comprising:
a processor; and
a memory including instructions embodied therewith that when executed by the processor perform an operation comprising:
determining an aggregate demand for power from the battery array;
performing one of discharging or charging via a first battery of the plurality of individual batteries from a first state of charge to a second state of charge based on a test profile configured to characterize the first battery, wherein the test profile is unrelated to the aggregate demand; and
performing the one of discharging or charging via a second battery of the plurality of individual batteries based on a difference between power discharged or charged by the first battery according to the test profile and the aggregate demand.

8. The system of claim 7, wherein the second battery is operated to cycle between a third state of charge and a fourth state of charge according to an operational profile for the second battery.

9. The system of claim 7, the operation further comprising:
charging a third battery of the plurality of individual batteries when the aggregate demand is exceeded by the power discharged from the first and second batteries.

10. The system of claim 7, the operation further comprising:
charging a fourth battery of the plurality of individual batteries from a third state to a fourth state according to a second test profile for the fourth battery while the first and second batteries discharge, wherein an amount of power to charge the fourth battery to the fourth state from the third state is included in the aggregate demand.

11. The system of claim 7, the operation further comprising:
updating an operational profile for the first battery after cycling the first battery from the second state back to the first state, wherein the operational profile identifies states of charge that the first battery is to operate between.

12. The system of claim 7, the operation further comprising:
when the one of discharging or charging is discharging and before discharging the first battery based on the test profile, ensuring that the aggregate demand has a total power demand equal to or greater than the power discharged by the first battery from the first state of charge to the second state of charge.

13. A method for managing power storage and discharge from or charge to a battery array that includes a plurality of individual batteries, the method comprising:
segmenting the battery array into:
a first battery group selected for characterization according to a test profile;
a second battery group selected as a backup charging source;
a third battery group selected as a backup discharging source; and
a fourth battery group;
isolating the first battery group, the second battery group, and the third battery group from a load served by the battery array while leaving the fourth battery group connected to supply stored power to the load;
performing a first one of discharging or charging via the second battery group from a first state of charge to a second state of charge via a second one of discharging or charging the first battery group from a third state of charge to a fourth state of charge according to the test profile; and
in response to the first battery group discharging or charging less power when discharging or charging from the third state of charge to the fourth state of charge than the second battery group draws when charging or supplies when discharging from the first state of charge to the second state of charge, supplementing the first battery group via the second one of discharging or charging the third battery group from a fifth state of charge to a sixth state of charge.

14. The method of claim 13, wherein the second battery group is discharged or charged from the first state of charge to the second state of charge according to a second test profile.

15. The method of claim 13, wherein the third battery group is selected based on an operational profile of the batteries comprising the third battery group and a difference between a power demand for discharging or charging the second battery group and a power output or power demand from the first battery group.

16. The method of claim 13, wherein the second battery group is discharged or charged from the first state of charge to the second state of charge according to a second test profile; and wherein the third battery group is selected based on an operational profile of the batteries comprising the third battery group and a difference between a power demand for discharging or charging the second battery group and a power output or power demand from the first battery group.

17. The method of claim 1, wherein the second battery is operated to cycle between a third state of charge and a fourth state of charge according to an operational profile for the second battery; and further comprising:
charging a third battery of the plurality of individual batteries when the aggregate demand is exceeded by the power discharged from the first and second batteries.

18. The method of claim 17, further comprising:
charging a fourth battery of the plurality of individual batteries from a third state to a fourth state according to a second test profile for the fourth battery while the first and second batteries discharge, wherein an amount of power to charge the fourth battery to the fourth state from the third state is included in the aggregate demand.

19. The method of claim 17, further comprising:
updating an operational profile for the first battery after cycling the first battery from the second state back to the first state, wherein the operational profile identifies states of charge that the first battery is to operate between.

20. The method of claim 17, further comprising:
wherein the one of discharging or charging is discharging and before discharging the first battery based on the test profile, ensuring that the aggregate demand has a total power demand equal to or greater than the power discharged by the first battery from the first state of charge to the second state of charge.
